(19) United States
(12) Patent Application Publication
(10) Pub. No.: US 2025/0274088 A1
(43) Pub. Date: Aug. 28, 2025

(54) ENERGY-EFFICIENT ACTIVE RECONFIGURABLE INTELLIGENT SURFACE WITH INTEGRATED SUB-ARRAY POWER AMPLIFIERS AND SIGNAL COUPLING

(71) Applicant: Dell Products L.P., Round Rock, TX (US)

(72) Inventors: Navjot Kaur Khaira, Kanata (CA); Tejinder Singh, Kanata (CA)

(21) Appl. No.: 18/586,838

(22) Filed: Feb. 26, 2024

(51) Int. Cl. H03F 3/24; H01P 3/08; H03K 5/00

(52) U.S. Cl. CPC H03F 3/245; H01P 3/081; H03K 2005/00013

(57) ABSTRACT

The technology described herein is directed towards a design and implementation of a subarray of unit cells for an active reconfigurable intelligent surface that is power efficient. The reconfigurable intelligent surface design integrates a power amplifier with subarrays of unit cells to amplify the reflected signal, resulting in an active reconfigurable intelligent surface with relatively low power consumption. For example, rather than equipping each unit cell with its own power amplifier, a power amplifier is shared by a m×n (e.g., 3×3) subarray of unit cells, which can be arranged as a module of a larger reconfigurable intelligent surface. Further, the design provides a device for receiving and reflecting the electromagnetic signal in the same polarization by coupling the RF energy, processing, amplifying, and then introducing a delay module to not create unwanted harmonics and amplifying the signal without breaking the signal link.

### BACKGROUND

Reconfigurable intelligent surfaces (alternatively referred to as intelligent reflective surfaces, or metasurfaces) are man-made thin reflective or refractive surfaces whose electromagnetic response can be electronically controlled. Reconfigurable intelligent surfaces are characterized by their two-dimensional arrays of electronically controllable reflecting elements that can dynamically manipulate electromagnetic waves by altering attributes such as phase, amplitude, and direction of the incoming signal. Because of their ability to alter the attributes of signals reflected at the surface, intelligent reflective surfaces are being evaluated for use in beyond fifth generation (B5G) and sixth generation (6G) wireless communication and wireless sensing networks.

In communications assisted by a reconfigurable intelligent surface, signal strength at the receiver is significantly constrained by the distance the signal needs to travel. Increasing the size of the reconfigurable intelligent surface is a common method to counteract free-space signal loss, but this can be costly and energy-intensive.

### BRIEF DESCRIPTION OF THE DRAWINGS

The technology described herein is illustrated by way of example and not limited in the accompanying figures in which like reference numerals indicate similar elements and in which:

FIG. 1 is an example conceptual block diagram showing a unit cell of a reconfigurable intelligent surface for reflecting an amplified and delayed incoming signal, in accordance with various example embodiments and implementations of the subject disclosure.

FIG. 2 is an example conceptual block diagram showing unit cells of a subarray of a reconfigurable intelligent surface that share circuitry for reflecting an amplified and delayed incoming signal, in accordance with various example embodiments and implementations of the subject disclosure.

FIG. 3 is a representation of an example design of a subarray that includes a power dividing and combining circuit on a dielectric substrate, in accordance with various example embodiments and implementations of the subject disclosure.

FIG. 4 is an exploded view representation of the example design of FIG. 3 showing a stack of layers of the subarray, in accordance with various example embodiments and implementations of the subject disclosure.

FIG. 5 is top view representation of the example design of FIG. 3 along with a representation of combining subarrays into a larger reconfigurable intelligent surface, in accordance with various example embodiments and implementations of the subject disclosure.

FIGS. 6-8 are top view representations showing various combinations of the layers of FIG. 4, in accordance with various example embodiments and implementations of the subject disclosure.

FIG. 9 is a graphical representation comparing an example active reconfigurable intelligent surface as described herein versus a passive reconfigurable intelligent surface when the incoming RF signal is normal to the reconfigurable intelligent surface, in accordance with various example embodiments and implementations of the subject disclosure.

FIG. 10 is a graphical representation showing simulated reflected signal amplitudes for the incoming signal with angles of arrival of θ=15°, 30°, and 45°, in accordance with various example embodiments and implementations of the subject disclosure.

### DETAILED DESCRIPTION

The technology described herein is generally directed towards integrating power amplifiers with reconfigurable intelligent surfaces. In one example implementation, power amplifiers are surface mounted onto components (reconfigurable intelligent surface elements) of a reconfigurable intelligent surface during the fabrication process.

However, because power amplifiers can consume significant power, the technology described herein facilitates balancing the amplification needs with power efficiency to ensure the system does not consume excessive energy, including in large-scale deployments. More particularly, to avoid the high cost and power demands of outfitting each reconfigurable intelligent surface element with a power amplifier, a more efficient approach is adopted by integrating a power amplifier with every m×n (e.g., 3×3) cluster of elements. Proper impedance matching between the power amplifiers and the reconfigurable intelligent surface elements is maintained by using a matching circuit to minimize signal reflection.

In one or more example implementations, reconfigurable intelligent surface elements (unit cells) with concentric ring-shaped metallic patterns can be used; notwithstanding, any arbitrary shape can be used, provided that the elements resonate at the desired wireless communication frequency. Further, in one or more example implementations, to get a wide bandwidth response, two hourglass shaped slots are used to passively couple the RF energy from the incoming signal (receive slots) and then transmit the outgoing delayed and amplified signal via coupled RF energy through the transmitting slots.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. For example, “optimal” placement of a subnet means selecting a more optimal subnet over another option, rather than necessarily achieving an optimal result. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there are no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

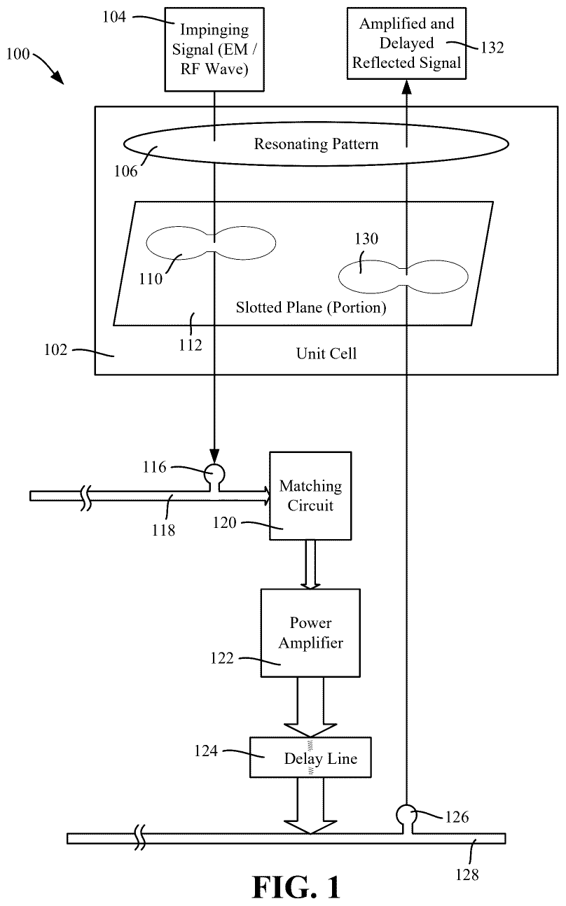

FIG. 1 is a conceptual depiction of an example system 100 including a unit cell 102 that redirects (reflects or refracts) an impinging (incoming) signal 104, (an electromagnetic (EM)/radio frequency (RF) wave, such as near or within the millimeter wavelength, e.g., above 25 gigahertz). A metallic resonating pattern 106 (e.g., a concentric ring-shaped metallic pattern) resonates at a frequency that corresponds to the frequency of the incoming signal. As set forth herein, a unit cell 102 can have a resonating pattern 106 of any suitable shape (e.g., square, rectangular and so on) that resonates at a corresponding frequency of the incoming signal, and is thus not limited to concentric ring patterns.

A first opening 110 (e.g., an hourglass-shaped opening) in a slotted plane 112 beneath and electrically insulated from the metallic resonating pattern 106 passes (e.g., couple/transfers) the signal 106 to a contact/terminal 116 of a first microstrip line 118 that is beneath and electrically insulated from the slotted plane 112. The slotted plane, which blocks the incoming RF signal (except via the opening 110) can be divided into electrically separated portions, e.g., one per unit cell, to help mitigate potential interference with respect to other unit cells. As set forth herein, a unit cell 102 can have an opening 110 of any suitable shape and size that passes the corresponding frequency of the incoming signal 104, and is thus not limited to hourglass-shaped openings.

The first microstrip line 118 is coupled via an impedance matching circuit 120 to a power amplifier 122 such that the incoming signal passed to the terminal 118 is amplified. The output of the amplifier is coupled to a delay line 124 that delays the amplified signal. The delayed, amplified signal thus can be of the same polarization as the incoming signal, because the delay mitigates interference between the incoming signal and the amplified signal to be output.

In this example, the delay line 124 electrically couples the amplified (and delayed) signal to a contact/terminal 126 of a second microstrip line 128. Via the contact/terminal 126, the amplified and delayed signal is passes through a second opening 130 (e.g., an hourglass-shaped opening) in the slotted plane 112, by which the amplified and delayed signal reaches the resonating pattern 106, resulting in an amplified and delayed redirected (e.g., reflected) signal 132.

As will be understood, the matching circuit 120, power amplifier 122 and delay line 124 are shared, via the first microstrip line 118 and the second microstrip line 128, with one or more other unit cells. This reduces the high energy cost associated with each power amplifier. For example, a 3×3 subarray (subgroup) of unit cells based on the shared power amplifier design described herein results in only one amplifier for each subarray of nine unit cells, or one-ninth of the energy consumed by having a power amplifier per unit cell. As can be readily appreciated, instead of the 3×3 subarray used in the examples herein, other subarrays can be used, e.g., 2×2, 4×4, 5×5 and so on, depending on the tradeoff between power usage and the strength of the amplified reflected signal. Moreover, a non-symmetrical subgroup/subarray can be used, e.g., 3×4, 3×5 and so on; however symmetrical subgroups having the same number of unit cells in each dimension (m=n) allow for modular design, as does having a reconfigurable intelligent surface made of same-sized subarrays, which also keeps design computations straightforward. The gain can be increased by less elements per amplifier, while the reflected beam is narrowed by more elements per amplifier; the cost versus elements per module/amplifier is a tradeoff that can be matched to a particular scenario where a reconfigurable intelligent surface is desired.

Thus, a significant enhancement to reconfigurable intelligent surface technology is described herein by the integration of power amplifiers. During the fabrication process, the power amplifiers can be surface mounted onto reconfigurable intelligent surface. To avoid the high cost and power demands of outfitting each reconfigurable intelligent surface element (unit cell) with a power amplifier, described herein is integrating a power amplifier with every m×n cluster of elements. Proper impedance matching between the power amplifiers and the reconfigurable intelligent surface elements is maintained by using the matching circuit to minimize signal reflection. In order to get a wide bandwidth response, two hourglass shaped slots are used to couple the RF energy from the incoming signal and then transmit the amplified signal.

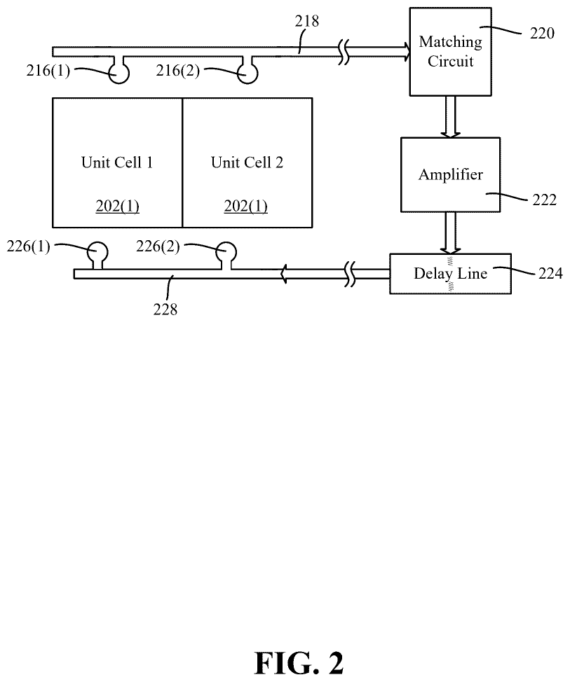

More particularly, FIG. 2 shows the concept of unit cells 202(1) and 202(2) sharing a matching circuit 220, power amplifier 222 and delay line 224. The first (incoming signal) microstrip line 218 has a contact/terminal 216(1) and 216(2) for the unit cells 202(1) and 202(2), respectively, to couple the incoming signal to the shared matching circuit 220, power amplifier 222 and delay line 224. The amplified and delayed output signal of the shared matching circuit 220, power amplifier 222 and delay line 224 is electrically coupled to the second microstrip line 228 which has a contact/terminal 226(1) and 226(2) for the unit cells 202(1) and 202(2), respectively, to couple the amplified and delayed signal to their respective metallic resonating patterns as generally described with reference to FIG. 1.

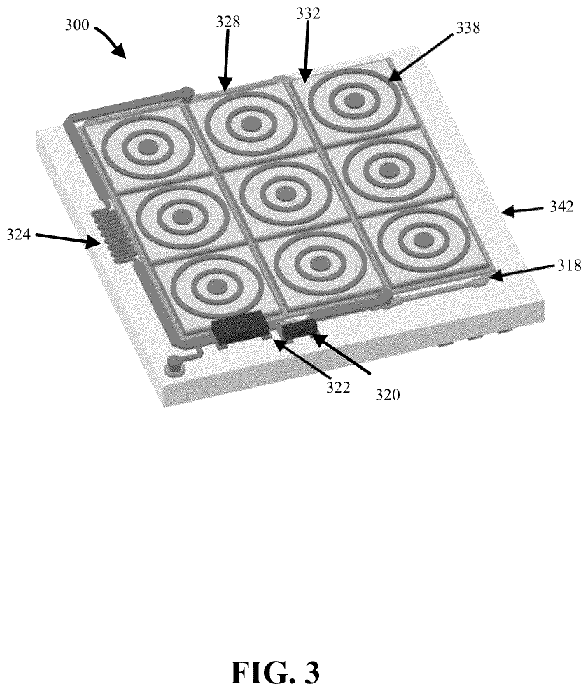

FIG. 3 shows a generally top-view perspective representation of an example fabricated 3×3 subarray 300 of unit cells, including the resonating patterns of each unit cell. The resonating pattern 338 of one unit cell 332 is labeled, with labels for the other resonating patterns of the other unit cells omitted for clarity. The unit cells rest on a dielectric substrate 342. Also depicted in FIG. 3 is first microstrip line 318, shown as electrically coupled to a matching circuit 320, power amplifier 322 and delay line 324. The delay line 324 electrically is coupled to a second microstrip line 328.

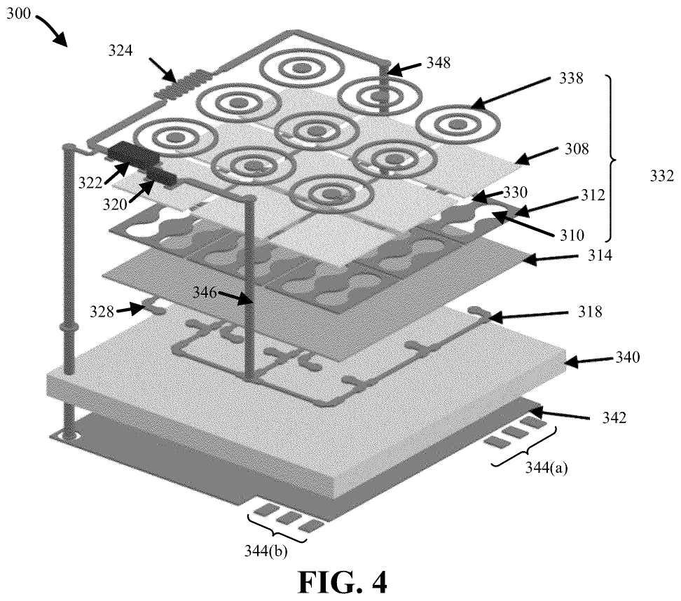

FIG. 4 shows an exploded view perspective representation of the example fabricated 3×3 subarray 300 of unit cells of FIG. 3, including the resonating patterns of each unit cell. As in FIG. 3, the resonating pattern 338 of one unit cell is labeled, with labels for the other resonating patterns of the other unit cells omitted for clarity. Note that an upper dielectric layer for each unit cell (e.g., 308) is shown as separated from the other dielectric layers of other unit cells, however a single shared dielectric layer may be used. The upper dielectric layer or layers are generally transparent to the frequency of the incoming and outgoing signals. A separate upper dielectric layer for each unit cell facilitates separate fabrication of each unit cell.

An interlayer via 346 routes the received signal from the first microstrip line to the surface mounted power amplifier 322. Another interlayer via 348 routes the delayed and amplified signal from the second microstrip line 328 to the resonating patterns at the surface. Still other interlayer vias can be used for the DC power.

In the reconfigurable intelligent surface based on the technology described herein, enhancing signal amplification is achieved by integrating power amplifiers into the reconfigurable intelligent surface, powered by an external DC voltage source. The power needed for the amplification functionality depends on the factors such as the type of power amplifier (PA) used, and the number of reconfigurable intelligent surface subarrays used in the complete reconfigurable intelligent surface panel. Different surface mounted device power amplifiers are commercially available, some of which are extremely power efficient depending on the technology used. For example, using a typical gallium nitride-based power amplifier at the targeted operating frequency range (26 to 28 GHz) in a 9×9 unit cell subarray needs V=20 V and I=350 mA, or a power P=7 W.

In the example representation of FIG. 4, the first opening and second paired openings of the slotted plane for each unit cell are depicted as side-by-side; one such first opening 310 and second 330 opening of a slotted plane portion 312 are labeled. A unit cell (e.g., the unit cell 332) thus includes the resonating metallic pattern, the upper dielectric layer 308 (which can be shared among unit cells), and the slotted plane portion 312 with RF coupling openings 310 and 330.

Beneath the slotted plane portions, including the slotted plane portion 312, is a lower dielectric layer 314, which is also generally transparent to the frequency of the incoming and outgoing signals. The lower dielectric layer 314 electrically insulates the unit cells' slotted plane portions from the first microstrip line 318, which is RF coupled to each unit cell, with the first microstrip line 318 electrically coupled to provide the input signal to the matching circuit 320, amplifier 322 and delay line 324. The output from the delay line 324 is coupled to the second microstrip line 328, to facilitate RF coupling of the unit cells to their respective resonating patterns.

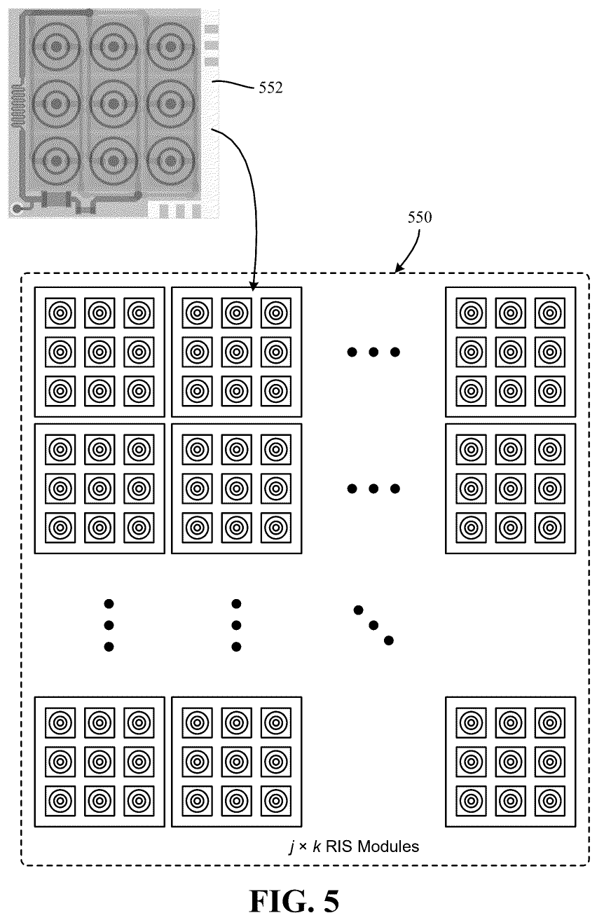

The components above and including the first microstrip line 318 and the second microstrip line 328 are supported on the dielectric substrate 340. A ground plane 342 is primarily beneath the dielectric substrate 340. In one implementation, terminals 344(a) and 344(b) for DC voltage to the circuitry (e.g., the matching circuit 320 and amplifier 322) are shown. The terminals facilitate modular construction of subarrays, such that multiple subarray modules can be used to assemble a larger intelligent reconfigurable surface, as generally depicted in the j×k intelligent reconfigurable surface (RIS) 550 of FIG. 5 composed of multiple 3×3 subarrays of unit cells, e.g., each identical to or similar to the fabricated (top view) subarray 552, which shows a multi-layer design layout of an example implementation of a RIS subarray.

To summarize, in one example implementation, the reconfigurable intelligent surface structure described here is organized into several 3×3 subarrays, with each subarray containing one power amplifier. This configuration allows for expansion to larger reconfigurable intelligent surface sizes while efficiently managing the number of power amplifiers used. The design detailed in FIGS. 3 and 4 shows a layering and integration of components within the reconfigurable intelligent surface. The construction of the reconfigurable intelligent surface is divided into four main metal layers, namely the reflecting patterns layer, a slotted plane (or planes layer), the microstrip network layers and a ground plane. Between every two metal layers, there is an intervening layer of dielectric material.

The power amplifier along with its peripheral circuit can be surface mounted on the topmost layer, which includes the resonating elements that receive the incoming signal. There are two kinds of slots under each element, namely a receiving slot (e.g., first opening 310) and a transmitting slot (e.g., second opening 330). The (e.g., hourglass-shaped) slot openings are used to avoid any sharp discontinuities that limit the performance bandwidth. Energy from the incoming signal is gathered by the receiving slots and then channeled to the subarray's combining circuit, which is then routed to the surface mounted power amplifiers from the inter-layer via 346 (FIG. 3). After amplification and delay, the dividing circuit (the second microstrip line 328) then distributes the amplified signal among the transmitting slots, whereby the signal is re-radiated from the top metallic elements.

Note that in one implementation, the design of the power dividing and combining circuit as described herein, along with the dielectric substrate, have been engineered to align with a characteristic impedance of 50 Ohms, targeting an operating frequency range centered at 28 GHz. Additionally, attention has been paid to the spacing between the microstrip lines of both the combining and dividing circuits, ensuring optimal separation to prevent any undesirable coupling between them. The delay line shown herein is used to provide a delay in the amplified signal before retransmission, because the amplified signal has the same polarization as the incoming signal. The delay line also creates a delay match between the combining and dividing circuit.

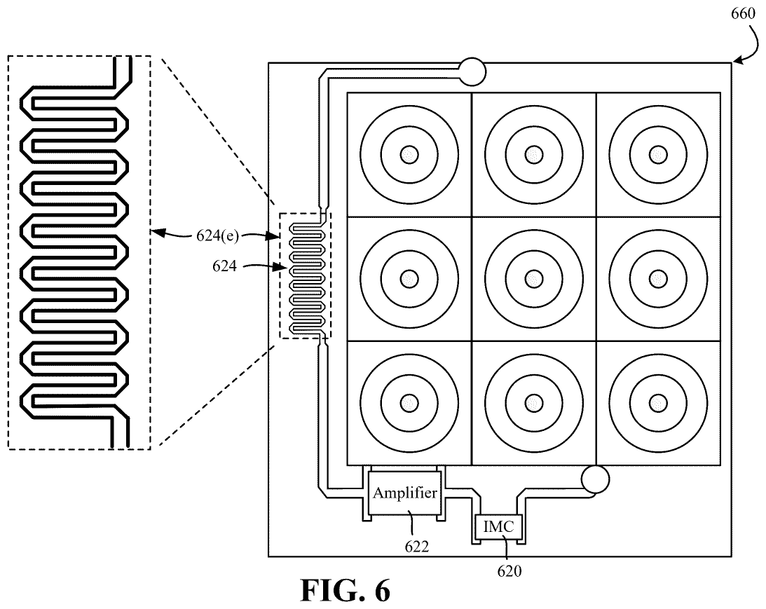

FIGS. 6-8 are top view representations of selected layers/levels of a subarray 660 of unit cells generally corresponding to the example subarray 552 of FIG. 5. The impendence matching circuit 620 and amplifier 622 are shown as part of the subarray 660 in FIGS. 6-8. FIG. 6 also shows an enlarged view 624 (e) of the meandering delay line 624; the line length is thus increased by the delay line 624 to provide a fixed delay; (a digital delay is also feasible). In one example implementation, the thickness, dielectric constant, and other characteristics of the dielectric layers are chosen such that an impedance of 50 Ohms is maintained.

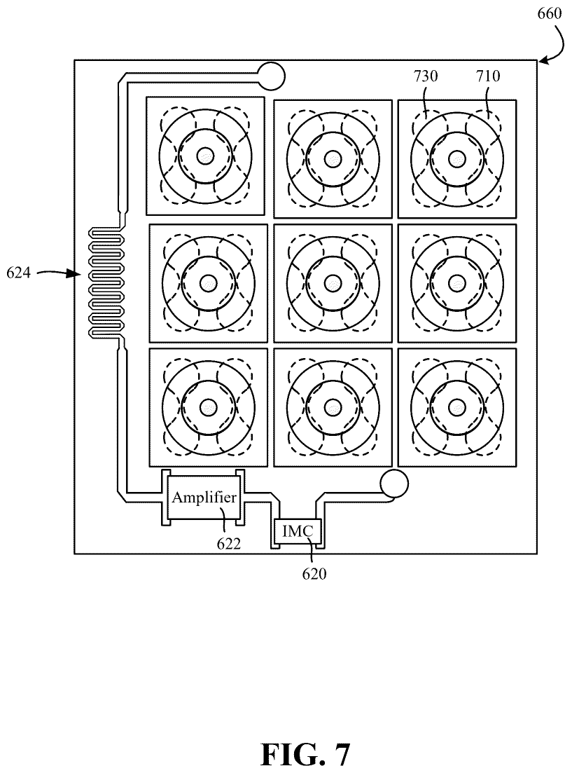

FIG. 7 is a top view corresponding to FIG. 6 that depicts the openings in the slotted plane layers beneath the top (resonating metallic pattern) layers and the upper dielectric layer. In this representation, the upper dielectric layer(s) are omitted to facilitate viewing of the slotted plane layers and their respective openings. One hourglass-shaped opening 710 for the incoming signal and one hourglass-shaped opening 730 for the outgoing amplified and delayed signal are labeled in FIG. 7.

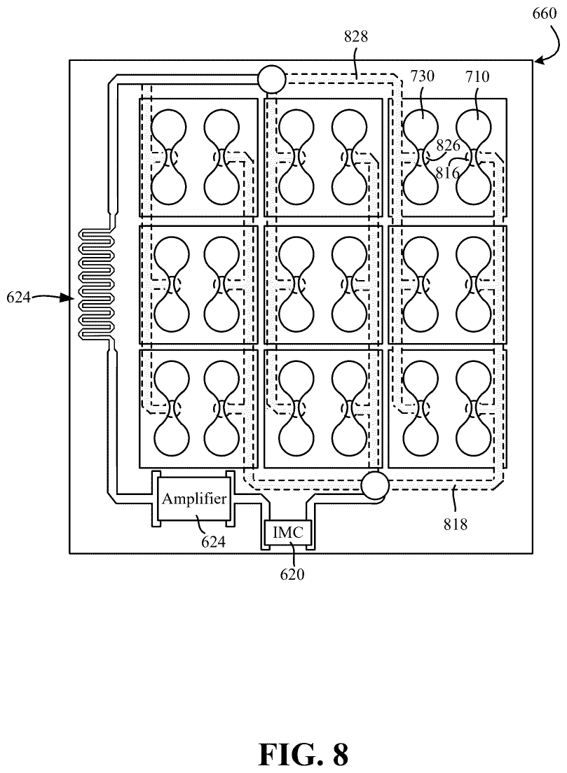

FIG. 8 is a top view corresponding to FIGS. 6 and 7 that depicts the next layer beneath the slotted plane layers and the lower dielectric layer and above the substrate, that is, FIG. 8 shows the openings in the slotted plane layers above the level of the first and second microstrip lines 818 and 828, respectively. In this representation, the lower dielectric layer is omitted to facilitate viewing of the first and second microstrip lines.

As can be seen in FIG. 8, the first and second microstrip lines 818 and 828 (shaded and dashed when depicted below the top layer) are shared by each unit cell of the subarray. As also can be seen, the first microstrip line 818 has respective contacts/terminals that align with the respective centers of the respective first openings in the unit cells' respective slotted plane layers. Thus, for example, the contact labeled 816 (of the first microstrip line 818) aligns with the first opening 710, while the contact labeled 826 (of the second microstrip line 828) aligns with the second opening 730. In this way, the incoming signal is RF energy coupled to the amplifier input, while the outgoing (delayed and amplified) signal is RF energy coupled to the amplifier output.

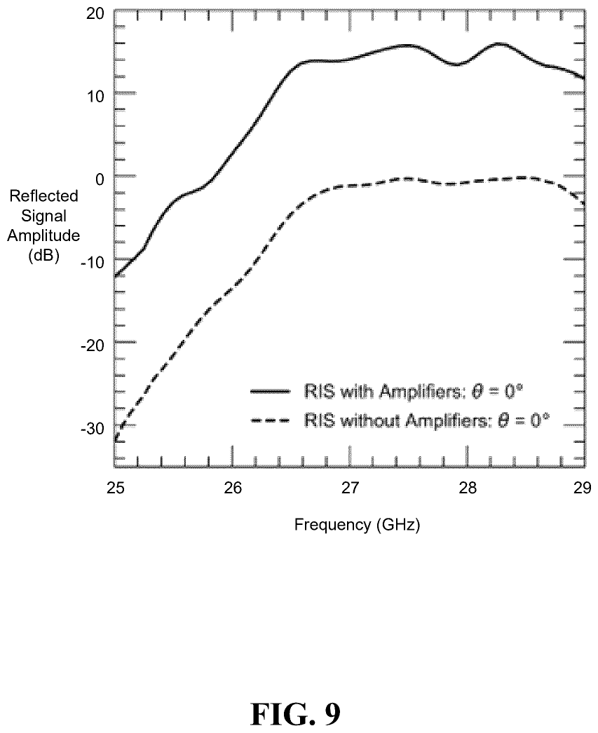

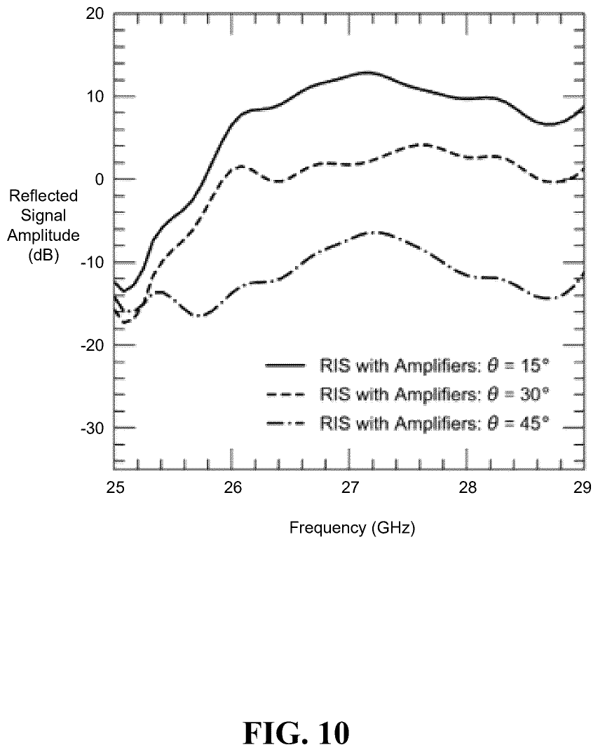

The design and evaluation of both the unit cell and the reconfigurable intelligent surface panel have been performed through comprehensive full wave simulations using 3D electromagnetic (EM) simulation software (e.g., Ansys HFSS). The results are shown in the graphical representations of FIGS. 9 and 10.

When the incident signal is normal to the surface of the evaluated reconfigurable intelligent surface, which means that the angle of arrival (AoA), θ is 0°, FIG. 9 shows the significant difference in reflected signal amplitude for the RIS with and without amplifiers. The passive gain of the evaluated reconfigurable intelligent surface lies between −2 dB and 0 dB from 26.5 GHz to 29 GHz, while the active gain is between 12 dB to 16 dB for the same frequency range.

FIG. 10 shows the active gain from RIS for the incoming signal AoAs (θ) of 15°, 30°, and 45°. More specifically, for the incident angle of 15°, the reflected signal amplitude is 9.5±3 dB for the frequency band 26 GHz to 29 GHz. When the incoming signal hits the surface at 30°, the amplified reflected signal amplitude is 2±2.1 dB. For the incident angle of 45°, the reflected signal amplitude is 10±4 dB for the frequency range 26 GHz to 29 GHz.

One or more example embodiments can be embodied in a system, such as described and represented herein. The system can include a subgroup of unit cells of a reconfigurable intelligent surface, the subgroup of unit cells electrically coupled to a power amplifier shared by the subgroup. The subgroup can be configured to receive an electromagnetic signal having a polarization to obtain a received electromagnetic signal, couple the received electromagnetic signal to a first microstrip line electrically coupled to the power amplifier to input the received electromagnetic signal to the power amplifier, amplify and delay the electromagnetic signal to output an amplified and delayed electromagnetic signal to a second microstrip line electrically coupled to the power amplifier, the amplified and delayed electromagnetic signal having a same polarization as the received electromagnetic signal, and couple the amplified and delayed electromagnetic signal from the second microstrip line to respective resonating metallic portions of respective unit cells of the subgroup, to combine and redirect the amplified and delayed electromagnetic signal from the subgroup.

The respective unit cells of the subgroup can couple the received electromagnetic signal to the first microstrip line via first respective openings of a slotted plane layer, and the respective unit cells of the subgroup can couple the amplified and delayed electromagnetic signal to the respective resonating metallic portions via second respective openings of the slotted plane layer. The first respective openings can be hourglass shaped. The second respective openings can be hourglass shaped. The first respective openings and second respective openings can be sized to correspond to a resonating frequency of the respective resonating metallic portions.

The power amplifier can be coupled to a delay line, the power amplifier can be configured to amplify the signal, and the delay line can be configured to delay the electromagnetic signal, to output the amplified and delayed electromagnetic signal.

Example embodiments can include an impedance matching circuit coupled to the power amplifier.

The subgroup can include a two-dimensional array of the respective unit cells. The two-dimensional array can include a first number of unit cells in a first dimension that equals a second number of unit cells in a second dimension. The two-dimensional array can include: four unit cells arranged as two unit cells by two unit cells, nine unit cells arranged as three unit cells by three unit cells, sixteen unit cells arranged as four unit cells by four unit cells, or twenty-five unit cells arranged as five unit cells by five unit cells. The two-dimensional array can include a first number of unit cells in a first dimension that does not equal a second number of unit cells in a second dimension.

The subgroup can include a first modular array of the respective unit cells that can be configured to couple to a second modular array of the reconfigurable intelligent surface.

One or more example embodiments can be embodied in a unit cell, such as described and represented herein. The unit cell can include a resonating metallic portion, and a slotted plane comprising a first opening configured to pass an impinging electromagnetic wave to a first microstrip line coupled to the unit cell, the unit cell coupled to a power amplifier that amplifies the impinging electromagnetic wave into an amplified electromagnetic wave obtained by a second microstrip line coupled to the unit cell. The slotted plane can include a second opening configured to pass the amplified electromagnetic wave from the second microstrip line to the resonating metallic portion to redirect the amplified electromagnetic wave as a reflected amplified electromagnetic wave.

Example embodiments can include a first dielectric layer between the resonating metallic portion and the slotted plane, a second dielectric layer between the slotted plane and the first microstrip line, and a dielectric substrate between the second microstrip line and a ground plane of the unit cell.

The unit cell can be a first unit cell, the reflected amplified electromagnetic wave can include a first instance of the reflected amplified electromagnetic wave from the first unit cell, the unit cell can be coupled to a second unit cell by the first microstrip line to share power amplifier, and to the second microstrip line; the reflected amplified electromagnetic wave can include a second instance of the reflected amplified electromagnetic wave from the second unit cell that combines with the first instance of the reflected amplified electromagnetic wave from the first unit cell.

The power amplifier can be coupled to a delay element that delays the amplified electromagnetic wave relative to the impinging electromagnetic wave to mitigate interference between the impinging electromagnetic wave and the amplified electromagnetic wave.

One or more example embodiments can be embodied in a device, such as described and represented herein. The device can include a subgroup of unit cells of a reconfigurable intelligent surface, the subgroup of unit cells electrically coupled to a power amplifier shared by the subgroup. Each unit cell can include a resonating metallic pattern corresponding to a resonating frequency, and a slotted plane comprising a first opening that passes impinging electromagnetic signals to a first contact of a first microstrip line, the first microstrip line coupled to an input of the power amplifier to output amplified electromagnetic signals to a delay line that outputs delayed amplified electromagnetic signals, the delay line coupled to a second contact of a second microstrip line that passes the delayed amplified electromagnetic signals through a second opening of the slotted plane to the resonating metallic pattern to redirect the impinging electromagnetic signals as delayed amplified electromagnetic signals.

The first opening and the second opening of each unit cell can be hourglass shaped and can be sized to correspond to the resonating frequency.

The subgroup can include a first subgroup arranged as a first modular array of the respective unit cells that is configured to couple to a second subgroup arranged as a second modular array of the reconfigurable intelligent surface.

The subgroup can include an impedance matching circuit coupled to the power amplifier.

As can be seen, the technology described herein is directed to a device for receiving and reflecting the electromagnetic signal, which can be in the same polarization, by first coupling the RF energy, impedance matching processing, amplifying, and then using a delay module to not create unwanted harmonics while amplifying the signal without breaking the signal link. The seamless monolithic integration of both the dividing and combining circuits, along with the power supply circuitry, results in a streamlined and organized design. Further, the design facilitates the use of only one power amplifier per m×n subarray of the surface's elements, which provides a significant decrease (e.g., 9 times for a 3×3 subarray) in the power amplifier power requirements, significantly reducing the cost, power, heat, and interference. The described design achieves a balance between reduced costs, added functionality and system complexity, ensuring that the incorporation of power amplifiers into the reconfigurable intelligent surface architecture does not overly complicate the system.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A system, comprising:
a subgroup of unit cells of a reconfigurable intelligent surface, the subgroup of unit cells electrically coupled to a power amplifier shared by the subgroup, the subgroup configured to:
receive an electromagnetic signal having a polarization to obtain a received electromagnetic signal;
couple the received electromagnetic signal to a first microstrip line electrically coupled to the power amplifier to input the received electromagnetic signal to the power amplifier;
amplify and delay the electromagnetic signal to output an amplified and delayed electromagnetic signal to a second microstrip line electrically coupled to the power amplifier, the amplified and delayed electromagnetic signal having a same polarization as the received electromagnetic signal; and
couple the amplified and delayed electromagnetic signal from the second microstrip line to respective resonating metallic portions of respective unit cells of the subgroup, to combine and redirect the amplified and delayed electromagnetic signal from the subgroup.

2. The system of claim 1, wherein the respective unit cells of the subgroup couple the received electromagnetic signal to the first microstrip line via first respective openings of a slotted plane layer, and wherein the respective unit cells of the subgroup couple the amplified and delayed electromagnetic signal to the respective resonating metallic portions via second respective openings of the slotted plane layer.

3. The system of claim 2, wherein the first respective openings are hourglass shaped.

4. The system of claim 2, wherein the second respective openings are hourglass shaped.

5. The system of claim 2, wherein the first respective openings and second respective openings are sized to correspond to a resonating frequency of the respective resonating metallic portions.

6. The system of claim 1, wherein the power amplifier is coupled to a delay line, wherein the power amplifier is configured to amplify the signal, and wherein the delay line is configured to delay the electromagnetic signal, to output the amplified and delayed electromagnetic signal.

7. The system of claim 1, further comprising an impedance matching circuit coupled to the power amplifier.

8. The system of claim 1, wherein the subgroup comprises a two-dimensional array of the respective unit cells.

9. The system of claim 8, wherein the two-dimensional array comprises a first number of unit cells in a first dimension that equals a second number of unit cells in a second dimension.

10. The system of claim 8, wherein the two-dimensional array comprises: four unit cells arranged as two unit cells by two unit cells, nine unit cells arranged as three unit cells by three unit cells, sixteen unit cells arranged as four unit cells by four unit cells, or twenty-five unit cells arranged as five unit cells by five unit cells.

11. The system of claim 8, wherein the two-dimensional array comprises a first number of unit cells in a first dimension that does not equal a second number of unit cells in a second dimension.

12. The system of claim 1, wherein the subgroup comprises a first modular array of the respective unit cells that is configured to couple to a second modular array of the reconfigurable intelligent surface.

13. A unit cell, comprising:
a resonating metallic portion;
a slotted plane comprising a first opening configured to pass an impinging electromagnetic wave to a first microstrip line coupled to the unit cell, the unit cell coupled to a power amplifier that amplifies the impinging electromagnetic wave into an amplified electromagnetic wave obtained by a second microstrip line coupled to the unit cell; and
the slotted plane comprising a second opening configured to pass the amplified electromagnetic wave from the second microstrip line to the resonating metallic portion to redirect the amplified electromagnetic wave as a reflected amplified electromagnetic wave.

14. The unit cell of claim 13, further comprising a first dielectric layer between the resonating metallic portion and the slotted plane, a second dielectric layer between the slotted plane and the first microstrip line, and a dielectric substrate between the second microstrip line and a ground plane of the unit cell.

15. The unit cell of claim 13, wherein the unit cell is a first unit cell, wherein the reflected amplified electromagnetic wave comprises a first instance of the reflected amplified electromagnetic wave from the first unit cell, wherein the unit cell is coupled to a second unit cell by the first microstrip line to share power amplifier, and to the second microstrip line, and wherein the reflected amplified electromagnetic wave comprises a second instance of the reflected amplified electromagnetic wave from the second unit cell that combines with the first instance of the reflected amplified electromagnetic wave from the first unit cell.

16. The unit cell of claim 13, wherein the power amplifier is coupled to a delay element that delays the amplified electromagnetic wave relative to the impinging electromagnetic wave to mitigate interference between the impinging electromagnetic wave and the amplified electromagnetic wave.

17. A device, comprising:
a subgroup of unit cells of a reconfigurable intelligent surface, the subgroup of unit cells electrically coupled to a power amplifier shared by the subgroup; and
each unit cell comprising:
a resonating metallic pattern corresponding to a resonating frequency; and
a slotted plane comprising a first opening that passes impinging electromagnetic signals to a first contact of a first microstrip line, the first microstrip line coupled to an input of the power amplifier to output amplified electromagnetic signals to a delay line that outputs delayed amplified electromagnetic signals, the delay line coupled to a second contact of a second microstrip line that passes the delayed amplified electromagnetic signals through a second opening of the slotted plane to the resonating metallic pattern to redirect the impinging electromagnetic signals as delayed amplified electromagnetic signals.

18. The device of claim 17, wherein the first opening and the second opening of each unit cell are hourglass shaped and sized to correspond to the resonating frequency.

19. The device of claim 17, wherein the subgroup comprises a first subgroup arranged as a first modular array of the respective unit cells that is configured to couple to a second subgroup arranged as a second modular array of the reconfigurable intelligent surface.

20. The device of claim 17, wherein the subgroup comprises an impedance matching circuit coupled to the power amplifier.
